(19) United States
(12) Patent Application Publication
(10) Pub. No.: US 2017/0077342 A1
(43) Pub. Date: Mar. 16, 2017

(54) APPARATUS FOR PRINTING ON A SUBSTRATE FOR THE PRODUCTION OF A SOLAR CELL, AND METHOD FOR TRANSPORTING A SUBSTRATE FOR THE PRODUCTION OF A SOLAR CELL

(71) Applicant: APPLIED MATERIALS ITALIA S.R.L., Via Postumia Ovest, 244 Frazione Olmi (IT)

(72) Inventors: Luigi DE SANTI, Spresiano (TV) (IT); Daniele GISLON, Santa Maria Di Sala- Venice (IT); Andrea BACCINI, Mignagola Di Carbonera (TV) (IT); Tommaso VERCESI, Aschaffenburg (DE); Gianfranco PASQUALIN, Spresiano (IT)

(21) Appl. No.: 15/122,075

(22) PCT Filed: Dec. 2, 2014
(86) PCT No.: PCT/EP2014/076239

§ 371 Date: Aug. 26, 2016

(51) Int. Cl. H01L 31/18; H01L 21/673; H01L 21/677

(52) U.S. Cl. CPC H01L 31/18; H01L 21/6776; H01L 21/67383

(57) ABSTRACT

The present disclosure provides an apparatus for printing on a substrate for the production of a solar cell. The apparatus includes two or more process stations; at least one substrate support configured to support the substrate; and at least one transport device configured to transport the at least one substrate support in a horizontal direction and in a vertical direction for transporting the at least one substrate support between the two or more process stations.

### TECHNICAL FIELD

Embodiments of the present disclosure relate to an apparatus for printing on a substrate for the production of a solar cell, and relate to a method for transporting a substrate for the production of a solar cell. Embodiments of the present disclosure particularly relate to an apparatus for screen printing on a substrate for the production of a solar cell.

### BACKGROUND OF THE DISCLOSURE

Solar cells are photovoltaic (PV) devices that convert sunlight directly into electrical power. Within this field, it is known to produce solar cells on a substrate such as a crystalline silicon base by means of printing techniques, such as screen printing, achieving on the front surface of the solar cells a structure of selective emitters.

An apparatus for manufacturing a solar cell may have a line configuration with a transportation path, wherein a plurality of process stations can be provided along the transportation path. The process stations may include one or more printing stations. Such an apparatus consumes considerable space for installation. For increasing production quantity, additional apparatuses can be installed, requiring even more installation space. Further, the apparatuses generate costs, e.g., in regard to operation and maintenance.

In view of the above, the present disclosure aims at providing an apparatus for printing on a substrate that is compact and/or is capable of producing an increased quantity of solar cells.

### SUMMARY OF THE DISCLOSURE

In light of the above, an apparatus for printing on a substrate for the production of a solar cell and a method for transporting a substrate for the production of a solar cell are provided. Further aspects, advantages, and features of the present disclosure are apparent from the dependent claims, the description, and the accompanying drawings.

According to an aspect of the present disclosure, an apparatus for printing on a substrate for the production of a solar cell is provided. The apparatus includes two or more process stations; at least one substrate support configured to support the substrate; and at least one transport device configured to transport the at least one substrate support in a horizontal direction and in a vertical direction for transporting the at least one substrate support between the two or more process stations.

According to another aspect of the present disclosure, an apparatus for printing on a substrate for the production of a solar cell is provided. The apparatus includes two or more process stations; at least one substrate support configured to support the substrate; and at least one transport device configured to transport the at least one substrate support in a horizontal direction and in a vertical direction for transporting the at least one substrate support between the two or more process stations, wherein the horizontal direction and the vertical direction define a substantially vertically oriented two-dimensional plane, and wherein the at least one transport device includes at least one alignment device configured for aligning at least one of a position and an angular orientation of the at least one substrate support in a horizontal plane.

According to yet another aspect of the present disclosure, a method for transporting a substrate for the production of a solar cell is provided. The method includes moving at least one substrate support in a horizontal direction and in a vertical direction for transporting the at least one substrate support between two or more process stations.

Embodiments are also directed at apparatuses for carrying out the disclosed methods and include apparatus parts for performing the described method steps. These method steps may be performed by way of hardware components, a computer programmed by appropriate software, by any combination of the two or in any other manner. Furthermore, embodiments according to the disclosure are also directed at methods for operating the described apparatus. It includes method steps for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIGS. 1A and 1B show perspective views of an apparatus for printing on a substrate for the production of a solar cell according to embodiments disclosed herein;

FIG. 2 shows a perspective view of an apparatus for printing on a substrate for the production of a solar cell according to further embodiments disclosed herein;

FIG. 3 shows a cross-sectional front view of the apparatus of FIG. 2 according to embodiments disclosed herein;

FIG. 4 shows a plan view of the apparatus of FIG. 2 according to embodiments disclosed herein;

FIG. 5 shows a side view of the apparatus of FIG. 2 according to embodiments disclosed herein;

FIGS. 6A and 6B show perspective views of a substrate support according to embodiments disclosed herein;

FIG. 7 shows a perspective view of an apparatus for printing on a substrate for the production of a solar cell according to further embodiments disclosed herein;

FIG. 8 shows a flowchart of a method for transporting a substrate for the production of a solar cell according to embodiments described herein; and

FIGS. 9 (a) to (l) show a sequence scheme for the production of solar cells using an apparatus according to embodiments disclosed herein.

### DETAILED DESCRIPTION OF EMBODIMENTS

Reference will now be made in detail to the various embodiments of the disclosure, one or more examples of which are illustrated in the Figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

According to an aspect of the present disclosure, an apparatus for printing on a substrate for the production of a solar cell is provided. The apparatus includes two or more process stations; at least one substrate support configured to support the substrate; and at least one transport device configured to transport the at least one substrate support in a horizontal direction and in a vertical direction for transporting the at least one substrate support between the two or more process stations.

In some implementations, a movement of the at least one substrate support for transporting the at least one substrate support between the two or more process stations has a vertical component and/or a horizontal component. As an example, the movement is a non-vertical upward or downward movement. According to some embodiments, the at least one transport device is configured to simultaneously transport the at least one substrate support in a horizontal direction and in a vertical direction, e.g., to provide the non-vertical upward or downward movement.

By providing substrate supports that can be moved both horizontally and vertically, the substrate supports can be arranged or stacked vertically. In view of this, the apparatus can be compact, requiring less installation space. Further, the vertically arranged substrate supports can simultaneously move from one process station to another process station without interfering with each other, and a throughput of the apparatus can be increased.

The term “vertical direction” or “vertical orientation” is understood to distinguish over “horizontal direction” or “horizontal orientation”. The vertical direction can be substantially parallel to the force of gravity.

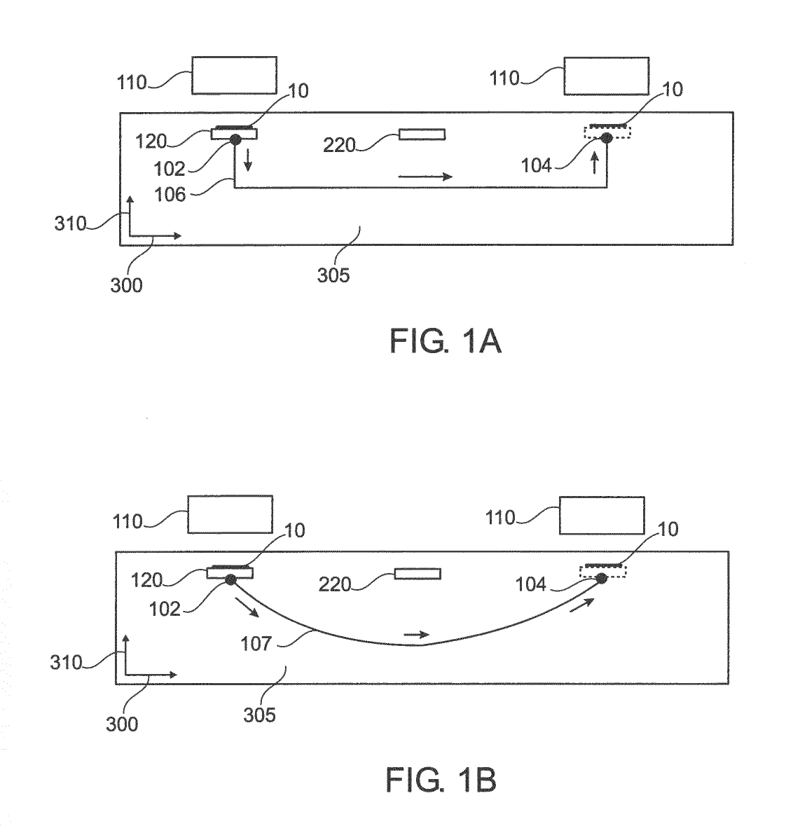

FIGS. 1A and 1B show perspective views of an apparatus for printing on a substrate 10 for the production of a solar cell according to embodiments disclosed herein.

The apparatus as exemplary illustrated may include two or more process stations 110; at least one substrate support, e.g., a first substrate support 120 and a second substrate support 220, configured to support the substrate 10; and at least one transport device (not shown) configured to transport the at least one substrate support in the horizontal direction 300 and in the vertical direction 310 for transporting the at least one substrate support between the two or more process stations 110.

According to some embodiments, which can be combined with other embodiments described herein, the horizontal direction 300 and the vertical direction 310 define a substantially vertically oriented two-dimensional plane 305. In other words, a vector of the horizontal direction 300 and a vector of the vertical direction 310 span the substantially vertically oriented two-dimensional plane 305, e.g., in Cartesian coordinates.

The term “substantially vertically oriented two-dimensional plane” is understood to distinguish over a “substantially vertically oriented two-dimensional plane”. That is, the “substantially vertically oriented two-dimensional plane” relates to a substantially vertical orientation of the two-dimensional plane 305, wherein a deviation of a few degrees, e.g. up to 10° or even up to 15°, from an exact vertical orientation is still considered as a “substantially vertical orientation”.

In some implementations, the at least one transport device is configured to transport the at least one substrate support along a transport path lying in the substantially vertically oriented two-dimensional plane 305.

In FIG. 1A, the at least one substrate support, e.g., the first substrate support 120, is transported along a first transport path 106. In FIG. 1B, the at least one substrate support, e.g., the first substrate support 120, is transported along a second transport path 107.

The transport path can include one or more process positions, e.g. a first process position 102 and a second process position 104. As an example, the first process position 102 corresponds to a position of a first process station of the two or more process stations 110. The second process position 104 can correspond to a position of a second process station of the two or more process stations 110. The at least one transport device can be configured to transport the at least one substrate support to at least one of the process positions for processing.

Referring to FIG. 1A, according to some embodiments, the at least one transport device is configured to transport the at least one substrate support sequentially in the horizontal direction 300 and in the vertical direction 310. The term “sequentially” may refer to vertical and horizontal movements of the at least one substrate support following in sequence, i.e., the vertical and horizontal movements are performed successively and not at the same time. As an example, the transport path can have one or more horizontal sections and one or more vertical sections. In particular, the transport path can be a discontinuous transport path, such as e.g. the first transport path 106 shown in FIG. 1A. The term “discontinuous” is to be understood in a mathematical sense.

Referring to FIG. 1B, according to some other embodiments, the at least one transport device is configured to transport the at least one substrate support simultaneously in the horizontal direction 300 and in the vertical direction 310. The term “simultaneously” may refer to vertical and horizontal movements of the at least one substrate support being performed at the same time. As an example, a moving direction or moving vector of the at least one substrate support can have a vertical component and a horizontal component. In particular, the transport path can be a continuous transport path, such as e.g. the second transport path 107 shown in FIG. 1B. The term “continuous” is to be understood in a mathematical sense. As an example, the transport path can be a continuously inclining, declining or a combination of an inclining and a declining transport path.

According to some embodiments, which can be combined with other embodiments described herein, the transport path includes one or more buffer positions. In some implementations, the buffer position is configured for storing at least one substrate. As an example, the buffer position can correspond to a position of a buffer device or buffer station configured for storing the at least one substrate. In some embodiments, the at least one transport device can be configured for transporting the at least one substrate support to one of the one or more buffer positions for waiting or storing the at least one substrate, e.g., when a target process position is occupied by another substrate support.

According to some embodiments, which can be combined with other embodiments described herein, the apparatus is configured for at least one of screen printing, ink-jet printing and laser processing. In some implementations, the laser processing may include creating holes in the substrate to create a pattern where a printing paste can be deposited for forming the printing structure. According to some embodiments, “laser processing” can also be referred to as “laser printing”.

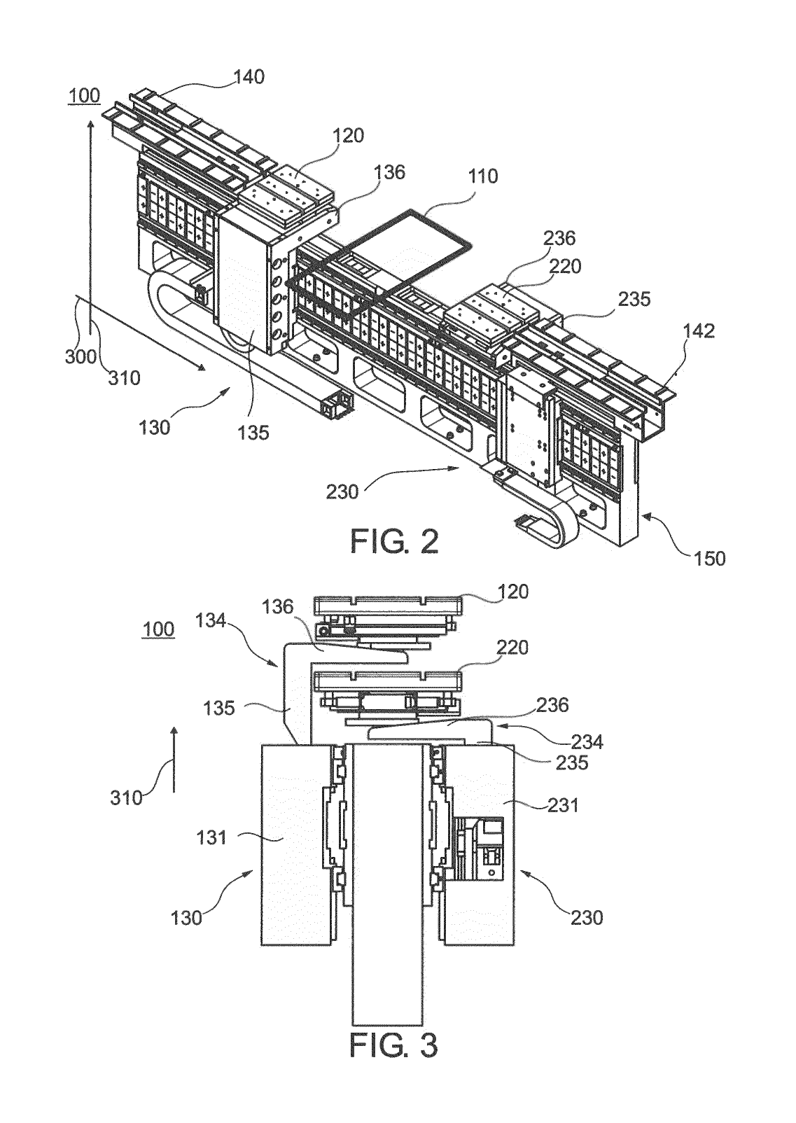

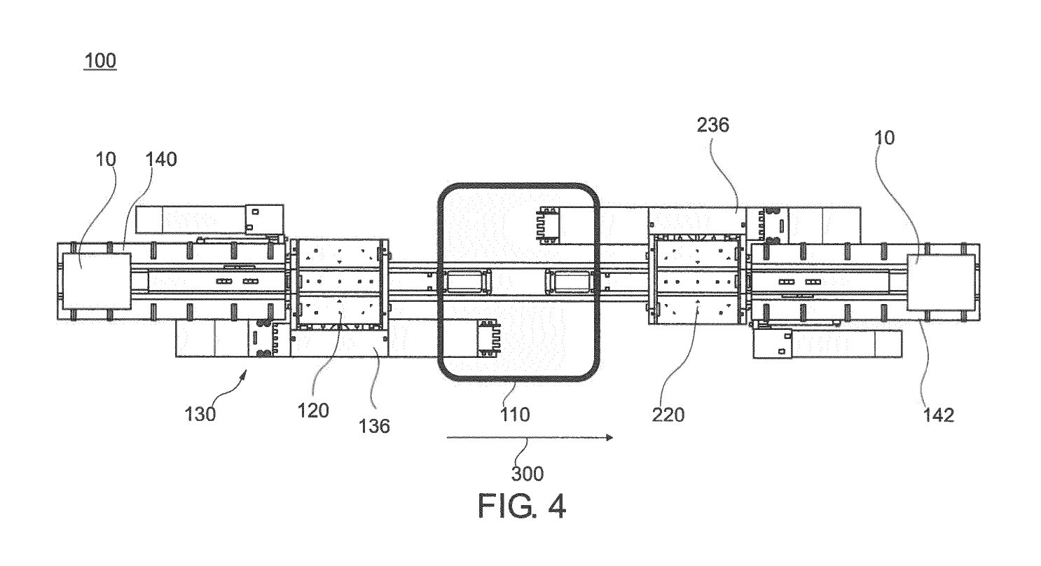

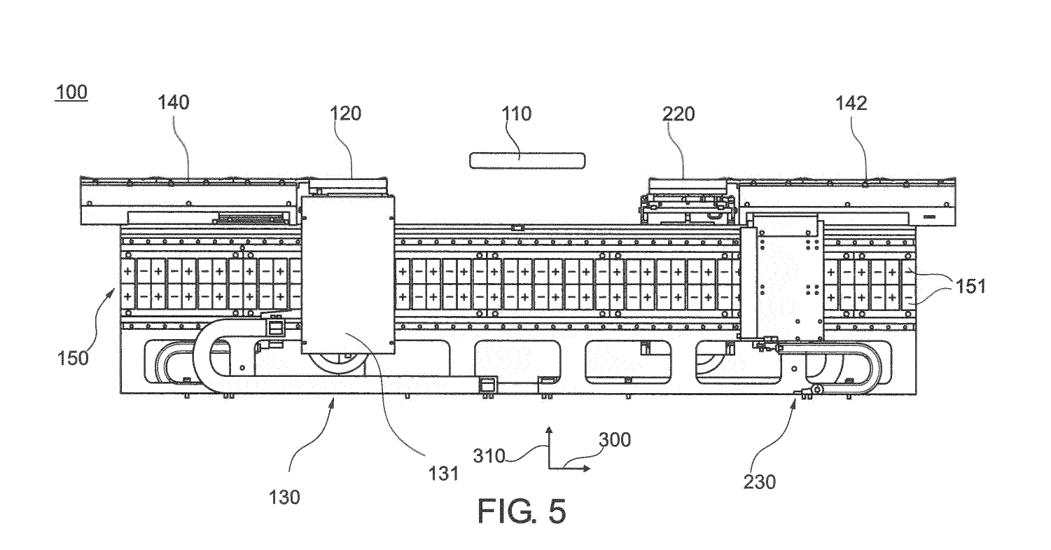

FIG. 2 shows a perspective view of an apparatus 100 for printing on a substrate 10 for the production of a solar cell according to embodiments disclosed herein. FIG. 3 shows a cross-sectional front view of the apparatus 100 of FIG. 2. FIG. 4 shows a plan view of the apparatus 100 of FIG. 2. FIG. 5 shows a side view of the apparatus 100 of FIG. 2.

The apparatus 100 as exemplary illustrated includes the two or more process stations 110; the at least one substrate support, e.g., a first substrate support 120 and a second substrate support 220, configured to support the substrate 10; and the at least one transport device, e.g., a first transport device 130 and a second transport device 230, configured to transport the at least one substrate support in the horizontal direction 300 and in the vertical direction 310 for transporting the at least one substrate support between the two or more process stations 110.

In some implementations, the apparatus 100 can include one or more conveyors, such as a first conveyor 140 and a second conveyor 142. The one or more conveyors can be configured for transferring an unprocessed substrate onto the first substrate support 120 and/or onto the second substrate support 220. Additionally or optionally, the one or more conveyors can be configured for transferring a processed substrate from the first substrate support 120 and/or from the second substrate support 220. As an example, the first conveyor 140 can be an incoming conveyor configured for receiving an unprocessed substrate from an input device (not shown), and can be configured to transfer the unprocessed substrate to the first substrate support 120 and/or the second substrate support 220. The second conveyor 142 can be an outgoing conveyor configured to receive a processed substrate from the first substrate support 120 and/or the second substrate support 220, and can be configured to transfer the processed substrate to a substrate removal device (not shown).

According to some embodiments, which can be combined with other embodiments described herein, the at least one transport device, e.g., the first transport device 130 and the second transport device 230, is configured to transport the at least one substrate support, such as the first substrate support 120 and the second substrate support 220, in the horizontal direction 300 and in the vertical direction 310. According to some embodiments, which can be combined with other embodiments described herein, the horizontal direction 300 and the vertical direction 310 define the substantially vertically oriented two-dimensional plane, as explained above with reference to FIG. 1.

According to some embodiments, which can be combined with other embodiments described herein, the at least one transport device includes a first motor for transporting the at least one substrate support in the vertical direction 310. As an example, the first motor is a linear motor. According to some embodiments, which can be combined with other embodiments described herein, the first motor is a stepper motor, a servo motor or a pneumatic motor. Particularly using a linear motor allows for a fine adjustment of the vertical position of the at least one substrate support.

In some implementations, the apparatus 100 includes a connection device configured for connecting the at least one transport device, and specifically the first motor, with the at least one substrate support. The connection device can be included in the at least one transport device. As an example, the apparatus 100 can include a first connection device 134 configured for connecting the first transport device 130, and specifically the first motor of the first transport device 130, with the first substrate support 120. Further, the apparatus 100 can include a second connection device 234 configured for connecting the second transport device 230, and specifically the second motor of the second transport device 230, with the second substrate support 220.

According to some embodiments, the connection device, such as the first connection device 134 and the second connection device 234, is substantially L-shaped. The substantially L-shaped connection device can include a first connection element extending substantially in the vertical direction 310, and can include a second connection element extending substantially in the horizontal direction 300. As an example, the first connection device 134 can include a first connection element 135 and a second connection element 136. The second connection device 234 can include another first connection element 235 and another second connection element 236. In some implementations, the first connection element can be configured for a connection with the at least one transport device, and the second connection element can be configured for a connection with the at least one substrate support.

The term “extending substantially in the vertical direction” is understood to distinguish over “extending substantially in the horizontal direction”. That is, “extending substantially in the vertical direction” relates to a substantially vertical extension, e.g., of the first connection element, wherein a deviation of a few degrees, e.g. up to 10° or even up to 30°, from an exact vertical extension is still considered as a substantially vertical extension. Similarly, “extending substantially in the horizontal direction” relates to a substantially horizontal extension, e.g., of the second connection element, wherein a deviation of a few degrees, e.g. up to 10° or even up to 30°, from an exact horizontal extension is still considered as a substantially horizontal extension.

According to some embodiments, which can be combined with other embodiments described herein, the at least one transport device includes a second motor 150 for transporting the at least one substrate support in the horizontal direction 300. As an example, the second motor 150 is a linear motor. According to some embodiments, which can be combined with other embodiments described herein, the second motor is a stepper motor, a servo motor or a pneumatic motor. Particularly using a linear motor allows for a fine adjustment of the vertical position of the at least one substrate support.

In some implementations, the at least one transport device includes a static or non-moving portion and a moveable portion, such as a first moveable portion 131 of the first transport device 130 and a second moveable portion 231 of the second transport device 230. As an example, the second motor 150 can include magnets 151 that are fixed in position, and the second motor 150 can include coils that are moving at least horizontally together with the moveable portion of the transport device. As a further example, the moveable portion can include the first motor of the transport device, so that the first motor is moveable along the horizontal direction 300 together with the at least one substrate support.

According to some embodiments, which can be combined with other embodiments described herein, the apparatus includes an inspection system configured for detecting a position and/or an orientation of the substrate positioned on the at least one substrate support. The inspection system can be included in at least one of the two or more process stations, e.g., an inspection station or an alignment station.

According to some embodiments, which can be combined with other embodiments described herein, the apparatus 100 further includes an alignment device configured for aligning at least one of a position and an angular orientation of the at least one substrate support in a horizontal plane. The alignment device allows an adjustment of the position and/or orientation of the substrate e.g. with respect to a printing device for an alignment of a printed pattern with a subsequently printed pattern. In particular, the alignment device allows for an alignment of the substrate so that the patterns printed on the substrate can be aligned with respect to the substrate and/or with respect to each other.

According to some embodiments, which can be combined with other embodiments described herein, the alignment device can use data obtained by the inspection system to align at least one of a position and an angular orientation of the at least one substrate support in the horizontal plane. As an example, the location and/or orientation of the substrate on the at least one substrate support is detected e.g. by the inspection system, and the detected location and/or orientation of the substrate is used to position the substrate support and thus the substrate e.g. with respect to the printing device such as a printing head.

In some implementations, the alignment device is configured to position the at least one substrate support in the X-direction and the Y-direction, and/or is configured to adjust the angular orientation of the at least one substrate support to a target orientation. The X-direction and the Y-direction may be the X-direction and the Y-direction of a Cartesian coordinate system, and may in particular define the horizontal plane. The angular orientation may refer to an angular orientation of the at least one substrate support with respect to a target such as a printing device. As an example, the angular orientation can be defined as an angle (e.g., theta) between a first reference line at the substrate support and a second reference line at the target such as the printing device.

According to some embodiments, the alignment device can include one or more actuators for aligning the position and/or the angular orientation of the at least one substrate support in the horizontal plane. The one or more actuators can include a stepper motor, a pneumatic motor and/or a server motor. As an example, the alignment device can include three actuators, e.g., a first actuator for moving or positioning the substrate support in X-direction, a second actuator for moving or positioning the substrate support in Y-direction, and a third actuator for angularly moving or positioning the substrate support. In some implementations, the first actuator and the second actuator can be linear actuators, and/or the third actuator can be a rotary actuator.

According to some embodiments, which can be combined with other embodiments described herein, the alignment device is included in the transport device and/or in the substrate support.

In some implementations, a printing device (e.g., a printing head) included in the one or more process stations and the at least one substrate support are moveable with respect to each other for printing. In particular, the printing device and the at least one substrate support are moveable with respect to each other in the horizontal direction 300, e.g., the X-direction. As an example, the printing device is moveable in at least one direction such as the X-direction along the at least one substrate support for printing. In such a case, the at least on substrate support can hold its position, i.e., the at least one substrate support is not moving during printing. In another example, the printing device is fixed in position while the at least one substrate support is configured to move e.g. in X-direction with respect to the printing device for printing. In such a case, the printing device can hold its position, i.e., the printing device is not moving during printing, but the at least one substrate support is moving during printing. The printing device can be configured for screen printing, ink-jet printing or laser processing or laser printing.

According to some embodiments, which can be combined with other embodiments described herein, the two or more process stations are selected from the group including: a substrate loading station, a substrate unloading station, a printing station, an alignment station, a buffer station, an inspection station, a heating station, and combinations thereof. According to some embodiments, which can be combined with other embodiments described herein, the apparatus is configured for screen printing. As an example, the printing station may include one or more printing heads and one or more screen devices for screen printing of patterns such as fingers and busbars on the substrate for the production of a solar cell. In some embodiments, the screen device defines a pattern or features corresponding to a structure to be printed on the substrate, wherein the pattern or features may include at least one of holes, slots, incisions or other apertures.

In some implementations, the apparatus includes a squeegee, wherein the screen device is provided between the substrate support and the squeegee. The squeegee can be included in the printing head. The squeegee can be configured for printing, and in particular screen printing. In some embodiments, the squeegee and the screen device are moveable with respect to each other for printing. As an example, the squeegee is moveable in at least one direction along the screen device for printing. In such a case, the at least on substrate support can hold its position, i.e., the at least one substrate support is not moving during printing. In another example, the squeegee is fixed in position while the at least one substrate support is configured to move e.g. in X-direction with respect to the squeegee for printing. In such a case, the squeegee can hold its position, i.e., the squeegee is not moving during printing, but the at least one substrate support is moving during printing

According to another aspect of the present disclosure an apparatus for printing on a substrate for the production of a solar cell is provided. The apparatus includes two or more process stations; at least one substrate support configured to support the substrate; and at least one transport device configured to transport the at least one substrate support in a horizontal direction and in a vertical direction for transporting the at least one substrate support between the two or more process stations, the horizontal direction and the vertical direction defining a substantially vertically oriented two-dimensional plane, wherein the transport device includes an alignment device configured for aligning at least one of a position and an angular orientation of the substrate support in a horizontal plane.

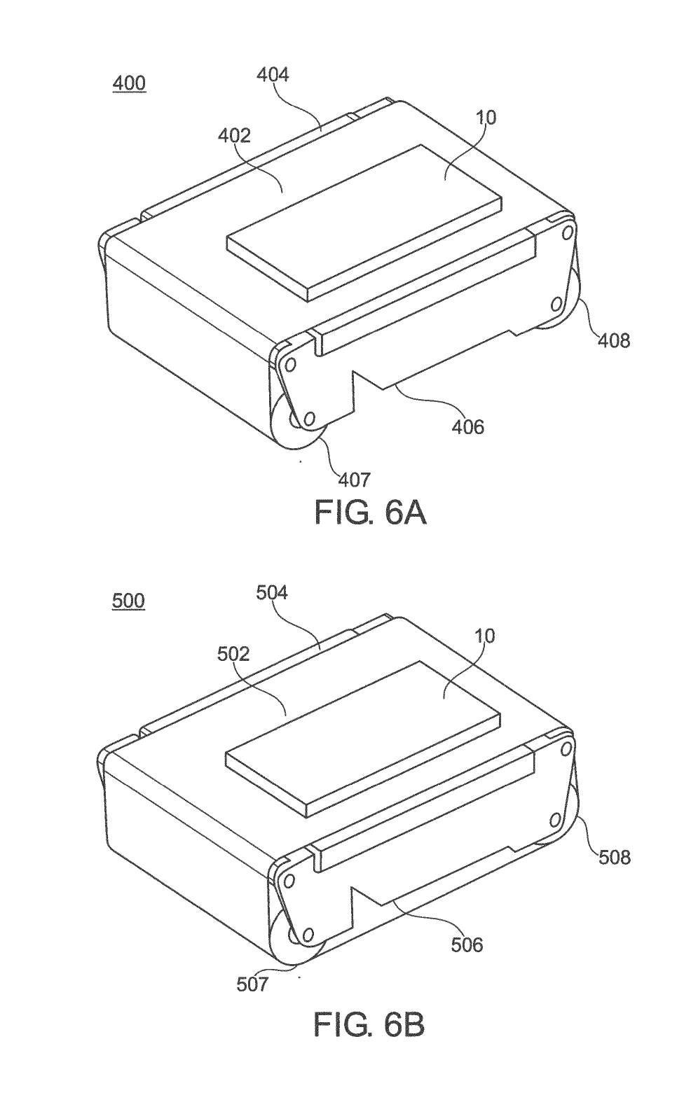

FIG. 6A shows a perspective view of a substrate support 400 according to embodiments disclosed herein. According to some embodiments, the substrate support can also be referred to as “processing nest”.

In some implementations, the substrate support 400 includes a conveyor device 406 having a feed roll 407 and a reception roll 408. The feed roll 407 and the reception roll 408 are configured to feed and retain a material 402 positioned on a surface 404 of the substrate support 400. According to some embodiments, the material 402 can be periodically removed and replaced.

According to some embodiments, which can be combined with other embodiments described herein, the substrate support 400 includes at least one suction device configured for holding the substrate 10 on the substrate support 400. As an example, the material 402 can be a porous material that allows the substrate 10 disposed on one side of the material 402 to be held to the surface 404 by a vacuum applied to the opposing side of the material 402 e.g. by vacuum ports formed in the surface 404. In some implementations, a vacuum is created by use of a vacuum source (not shown) coupled to the ports in the surface 404.

FIG. 6B shows a perspective view of a substrate support 500 according to further embodiments disclosed herein. According to some embodiments, the substrate support can also be referred to as “processing nest”. A conveyor device 506 of the substrate support 500 is configured as a continuous conveyor system having one or more first rollers 508 and one or more second rollers 507 for feeding the material 502 positioned across the surface 504. The surface 504 can support the substrate 10 and the material 502 during the processing, e.g., at a process station such as a printing station.

According to some embodiments, which can be combined with other embodiments described herein, the substrate support 500 includes at least one suction device configured for holding the substrate 10 on the substrate support 500. As an example, the material 502 can be a porous material that allows the substrate 10 disposed on one side of the material 502 to be held to the surface 504 by a vacuum applied to the opposing side of the material 502, e.g., by vacuum ports formed in the surface 504. In some implementations, a vacuum is created by use of a vacuum source (not shown) coupled to the ports in the surface 504. According to some embodiments, the material 502 is cleaned as it is fed by the one or more feed rollers 508.

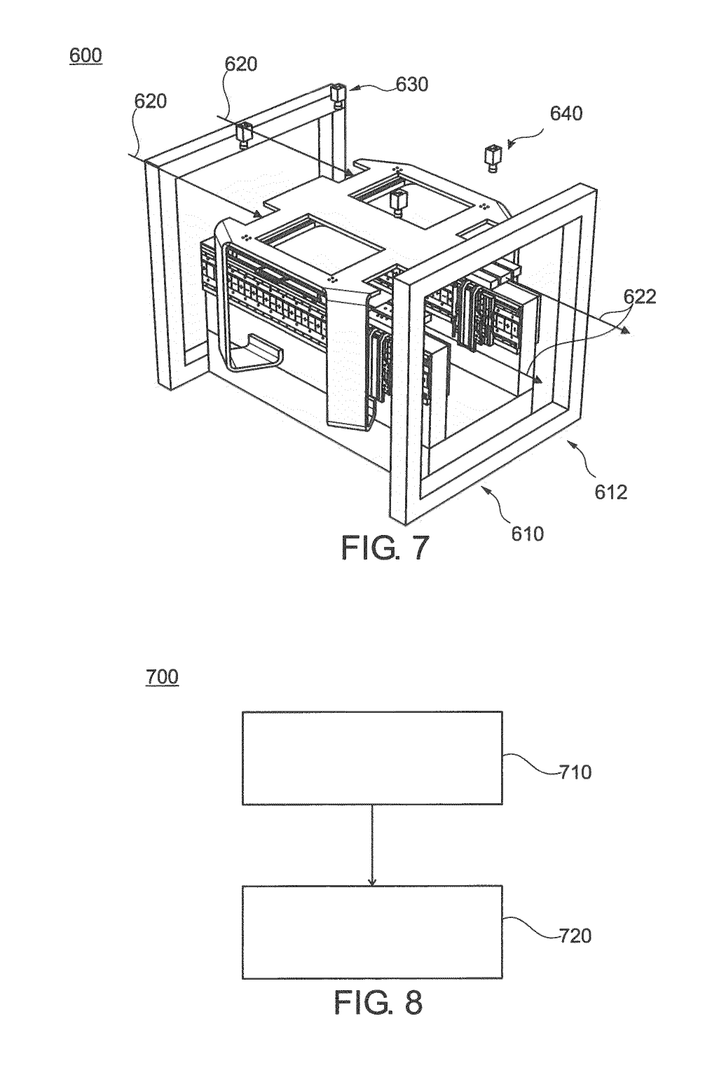

FIG. 7 shows a perspective view of a system 600 for printing on a substrate for the production of a solar cell according to embodiments disclosed herein.

The system 600 has a dual-line configuration and includes a first apparatus 610 for printing on a substrate for the production of a solar cell and a second apparatus 612 for printing on a substrate for the production of a solar cell.

In some implementations, the first apparatus 610 and the second apparatus 612 are arranged in parallel and provide two production lines for the production of solar cells. The first apparatus 610 and the second apparatus 612 can be operated independently from each other so that each of the first apparatus 610 and the second apparatus 612 is able to perform at least a part of a solar cell production process, and particularly a complete solar cell production process.

In other examples, the first apparatus 610 and the second apparatus 612 can be operated in cooperation so that the first apparatus 610 and the second apparatus 612 perform the solar cell production process together. As an example, the first apparatus 610 and the second apparatus 612 can include different process stations, wherein the at least one substrate support can be transferred from the first apparatus 610 to the second apparatus 612 and from the second apparatus 612 to the first apparatus 610.

The system 600 has an input 620 for inputting unprocessed substrates into the system 600. The input 620 can be a double-line input for inputting substrates in the first apparatus 610 and the second apparatus 612, respectively. The system 600 has an exit 622 for removing processed substrates out of the system. The exit 622 can be a double-line exit for removing substrate from the first apparatus 610 and the second apparatus 612, respectively.

According to some embodiments, the system includes a first inspection system 630 at or near the input 620. The first inspection system 630 can be used for alignment as described above with reference to FIGS. 1 to 5. According to some embodiments, the system includes a second inspection system 640 at or near the exit 622. The second inspection system 640 can be used for feedback and/or for quality inspection, e.g., of the printed patterns. As to the feedback, the second inspection system 640 can be configured for detecting a position and/or orientation of the patterns printed on the substrate and can provide the detected position and/or orientation to the alignment device, which may use the obtained information for the alignment of a subsequent substrate.

FIG. 8 shows a flowchart of a method 700 for transporting a substrate for the production of a solar cell according to embodiments described herein.

According to an aspect of the present disclosure, the method 700 includes moving at least one substrate support in a horizontal direction and in a vertical direction for transporting the at least one substrate support between two or more process stations (block 710). In some implementations, the method can further include simultaneously or sequentially moving the at least one substrate support in the horizontal direction and in the vertical direction (block 720).

According to some embodiments, the method uses the apparatus for printing on a substrate for the production of a solar cell according to the embodiments described herein.

According to embodiments described herein, the method for transporting a substrate for the production of a solar cell can be conducted by means of computer programs, software, computer software products and the interrelated controllers, which can have a CPU, a memory, a user interface, and input and output means being in communication with the corresponding components of the apparatus for processing a large area substrate.

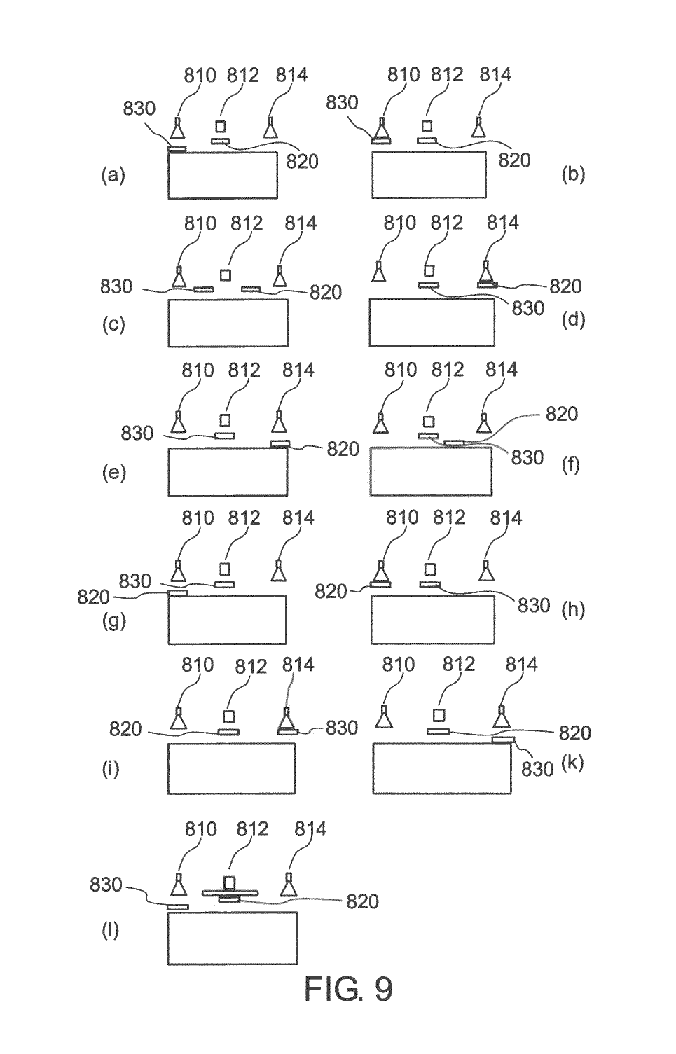

FIGS. 9 (a) to (l) show a sequence scheme for the production of solar cells using an apparatus and method according to embodiments disclosed herein.

The apparatus includes an alignment station 810, a printing station 812 and an inspection station 814. In FIG. 9, sections (a) to (l) show a sequence for simultaneously processing two substrates, i.e., a first substrate 820 and a second substrate 830.

In section (a), the first substrate 820 is positioned at the printing station 812, e.g., for printing of a first pattern on the first substrate 820, and the second substrate 830 is input in the apparatus. In section (b), the first substrate 820 is still positioned at the printing station 812 for printing the first pattern on the first substrate 820, and the second substrate 830 is positioned at the alignment station 810, e.g., for an initial alignment of the second substrate 830 with a printing head in the printing station, after having been moved vertically. In section (c), the first substrate 820 and the second substrate are moved at least horizontally until, in section (d), the second substrate 830 is positioned at the printing station 812, e.g., for printing a first pattern on the second substrate 830, and the first substrate 820 is positioned at the inspection station, e.g., for inspecting the first pattern printed on the first substrate 820.

In sections (e) to (h), the second substrate 830 is positioned at the printing station 812, e.g., for printing the first pattern on the second substrate 830. The first substrate 820 is moved vertically and horizontally from the inspection station 814 back to the alignment station 810 for alignment of the first substrate 820 or the first pattern printed on the first substrate 820, e.g., with the printing head in the printing station, so that a second pattern to be printed on the first substrate 820 is aligned with the first pattern on the first substrate 820.

In section (i), the second substrate 830 is positioned at the inspection station 814, e.g., for inspecting the first pattern printed on the second substrate 830, and the first substrate 820 is positioned at the printing station 812, e.g., for printing the second pattern on the first substrate 820. As an example, the first pattern and the second pattern may be fingers and busbars, respectively.

In sections (k) and (l), the second substrate 830 is moved vertically and horizontally from the inspection station 814 back to the alignment station 810 for alignment of the second substrate 830 or the first pattern printed on the second substrate 830, e.g., with the printing head in the printing station, so that a second pattern to be printed on the second substrate 830 is aligned with the first pattern on the second substrate 830.

It is noted that the above sequence of processing steps is not complete, and various additional sequence steps including a moving to, and processing at, further process stations could be provided to manufacture a solar cell.

While the foregoing is directed to embodiments of the disclosure, other and further embodiments of the disclosure may be devised without departing from the basic scope thereof, and the scope thereof is determined by the claims that follow.

1. An apparatus for printing on a substrate for production of a solar cell, comprising:
two or more process stations;
at least one substrate support configured to support the substrate; and
at least one transport device configured to transport the at least one substrate support in a horizontal direction and in a vertical direction for transporting the at least one substrate support between the two or more process stations.

2. The apparatus of claim 1, wherein the horizontal direction and the vertical direction define a two-dimensional plane, wherein the at least one transport device is configured for transporting the at least one substrate support in the two-dimensional plane.

3. The apparatus of claim 1, wherein the at least one transport device is configured to transport the at least one substrate support in the horizontal direction and in the vertical direction simultaneously or sequentially.

4. The apparatus of claim 1, wherein the at least one transport device includes a first motor for transporting the at least one substrate support in the vertical direction.

5. The apparatus of claim 4, wherein the motor is a stepper motor, a servo motor or a pneumatic motor.

6. The apparatus of claim 4, wherein the at least one transport device includes a second motor for transporting the at least one substrate support in the horizontal direction.

7. The apparatus of claim 1, further including at least one alignment device configured for aligning at least one of a position and an angular orientation of the at least one substrate support in a horizontal plane.

8. The apparatus of claim 7, wherein the at least one alignment device is included in the at least one transport device in the at least one substrate support.

9. The apparatus of claim 1, wherein the at least one substrate support includes at least one suction device configured for holding the substrate on the at least one substrate support.

10. The apparatus of claim 1, wherein the at least one substrate support includes a conveyor device configured for at least one of conveying the substrate onto the at least one substrate support and for conveying the substrate from the at least one substrate support.

11. The apparatus of claim 1, wherein the apparatus is configured for at least one of screen printing, ink-jet printing, and laser processing.

12. The apparatus of claim 1, wherein the two or more process stations are selected from the group consisting of:
a substrate loading station;
a substrate unloading station;
a printing station;
an alignment station;
a buffer station;
an inspection station;
a heating station; and
combinations thereof.

13. An apparatus for printing on a substrate for production of a solar cell, comprising:
two or more process stations;
at least one substrate support configured to support the substrate; and
at least one transport device configured to transport the at least one substrate support in a horizontal direction and in a vertical direction for transporting the at least one substrate support between the two or more process stations, wherein the horizontal direction and the vertical direction define a vertically oriented two-dimensional plane, and wherein the at least one transport device includes at least one alignment device configured for aligning at least one of a position and an angular orientation of the at least one substrate support in a horizontal plane.

14. A method for transporting a substrate for production of a solar cell, comprising:
moving at least one substrate support in a horizontal direction and in a vertical direction for transporting the at least one substrate support between two or more process stations.

15. The method of claim 14, further including:
simultaneously or sequentially moving the at least one substrate support in the horizontal direction and in the vertical direction.

16. The apparatus of claim 5, wherein the at least one transport device includes a second motor for transporting the at least one substrate support in the horizontal direction.

17. The apparatus of claim 7, wherein the at least one alignment device is included in the at least one transport device and in the at least one substrate support.

18. The apparatus of claim 14, wherein the two-dimensional plane is a vertically oriented two-dimensional plane.

19. The apparatus of claim 16, wherein the at least one transport device is configured for transporting the at least one substrate support along a transport path in the vertically oriented two-dimensional plane.

20. The method of claim 2, wherein the moving of the at least one substrate support includes moving along a transport path in a two-dimensional plane defined by the horizontal direction and the vertical direction.
